(19) United States
(12) Patent Application Publication
(10) Pub. No.: US 2009/0134646 A1
(43) Pub. Date: May 28, 2009

(54) AUTOMATIC SYSTEM FOR GUIDING, RETAINING AND ADJUSTING CABLES

(75) Inventors: Miguel Angel Tavio Diaz, San Roque(Cadiz) (ES); Manoli Vilchez Vilchez, Algeciras(Cadiz) (ES); Antonio Illana Martos, Algeciras(Cadiz) (ES)

Correspondence Address: CANTOR COLBURN, LLP, 20 Church Street, 22nd Floor, Hartford, CT, 06103, US

(73) Assignee: MAERSK ESPANA S.A., Algeciras (ES)

(21) Appl. No.: 12/282,147

(22) PCT Filed: Jul. 20, 2006
(86) PCT No.: PCT/ES2006/000423

§ 371 Date: Dec. 19, 2008

(30) Foreign Application Priority Data
Mar. 6, 2006 (ES) P200600667

(51) Int. Cl. B66D 5/26; H01L 21/683

(52) U.S. Cl. 294/119.2; 414/800

(57) ABSTRACT

The fastenings of the wire ropes for loading containers are subjected to huge stresses, making it necessary to use screwed-in robust grips.

The systems currently installed in these cranes for fixing ropes are fixed, screwed-in grips.

A much more versatile and flexible system is presented that is based on a wedge mechanism which allows automatic and instant actuation (remotely controlled).

The assembly includes the sliding clamps, the actuation of these clamps, necessary additional guides and tightening device for tightening the ropes.

This solution allows:
Performing the rope changing operation with the jib hoisted, thus allowing the maneuvers of vessels and the operation of contiguous cranes.
Reducing the rope replacement times.

Using the anchoring element (clamps)+tightening device as a mechanism for tightening the length of the ends. Possible misalignments of the spreader can be corrected instantly.

### FIELD OF THE ART

Industrial field: container transport and movement.

Steel wire ropes for cranes.

### STATE OF THE ART

Load ropes in container transport cranes are responsible for hoisting the load, hoisting the jib and, in the most frequent variants, translating the trolley. They are thick gauge, very long ropes without splicing that are subjected to strong loads and which must be periodically renewed. The ropes are anchored by means of fixed wedge terminals and fixed, screwed-in grips or clamps.

The rope changing operation (hoisting the load) currently requires many hours and is done with the jib of the crane in the horizontal position. This situation interferes with the maneuvers of contiguous vessels and cranes: it prevents docking maneuvers and changes in the position of the cranes while the rope changing operation lasts.

The ropes must be tightened such that the spreader (engaging element) is perfectly aligned and level with the container. Since the anchoring of the ropes is fixed, this operation has a significant cost in terms of hours and manual labor.

### DESCRIPTION OF THE INVENTION

### Technical Problem Considered

The rope changing operation requires immobilizing the crane for a considerable time. During this maneuver it is necessary to remove all the rope anchoring points and allow them to pass through the crane as easily as possible.

The position of the crane and jib in the dock creates interference problems with the remaining operations: vessel maneuvers and positioning of other cranes.

Anchoring the ropes at the end of the jib requires using equipment and tools for disassembling/assembling the clamps. This area has little space for personnel; it is pounded against by the wind and is exposed to problems due to falling objects and other risks inherent to working at elevated heights.

### BRIEF DESCRIPTION OF THE INVENTION

A system is described which allows automatic, instant and remote-controlled actuation.

The assembly (FIG. 1) includes sliding clamps (FIG. 2), the actuation of these clamps, additional guidance system and automatic tightening device for tightening the ropes.

The clamps (FIG. 2) are based on a wedge mechanism having a suitable shape and angles so as to be self-blocking, to exert enough pressure without damage the rope and to be actuated with a force that is much lower than the strain of the rope they support. If the clamp actuator was to fail, the friction between the rope and wedges would keep the latter in the closed position.

Automatic operations and the jib in the vertical position make better guidance of the run of the rope necessary. The tightening device in turn increases the force on the sheaves; therefore said sheaves and their support shafts must be reinforced.

### DETAILED DESCRIPTION OF THE INVENTION

The proposed system (FIG. 1) requires an automatic clamp for each end of the rope. Only one tightening device needs to be used, although variants could be designed with independent tightening devices or with common actuations for the clamps.

The system consists of: four clamps, one for each end, with their respective actuations. The clamp is formed by two sliding wedges and a rigid casing. The actuation is gauged such that it can close or open the wedges.

The sheaves guide the rope, preventing the clamps from receiving transverse stresses and preventing the rope from being rubbed or from experiencing heavy bending. Furthermore, the slack portions that are formed aid in tightening the rope and leveling the spreader increasing or decreasing the run of the rope by means of the tightening device and the selective closing of the corresponding clamp.

### BRIEF DESCRIPTION OF THE DRAWINGS

FIG. 1 shows the arrangement of the device. It is depicted with the direct linear arrangement of the tightening device and of the four clamps by means of hydraulic cylinders. It should be mentioned that this is only one variant among many possible variants (pneumatic cylinders, solenoids, electric motors, worm gear transmission, etc).

The sheaves, with the additional guidance device, are arranged such that both ropes are maintained in parallel planes, without the possibility of rubbing against one another when they are under load.

The tightening device has a relatively broad run, the effect of which is increased by the arrangement of the inner sheaves.

The outer sheaves maintain the coaxiality between the ropes and the axis of the clamps.

Immediate variants of the proposed system are obtained by changing the order between components, changing the number of clamps or tightening devices, or by placing the latter in other directions and maintaining guidance by means of sheaves, bolts or other suitable elements.

FIG. 2 is a detail of FIG. 1 showing a possibility of operating the clamps, located in the open position. There are two independent wedges inside the casing, sliding on inclined planes. The actuator of the wedges is a hydraulic cylinder, the rod of which has been located close to the axis of the clamps to minimize bending stresses.

The casing is very robust since it must resist high normal forces which tend to open its side walls. A variant with two milled plates screwed together is shown, although there are many other possibilities.

### PREFERRED EMBODIMENT OF THE INVENTION

The figures shown correspond with a specific embodiment. The five actuations are hydraulic cylinders, forming part of the same circuit. The hydraulic station (not shown) is arranged in the same area.

The mobile wedges have two clearly different faces. The outer wall slides on the casing and is rectified in order to reduce friction. The inner wall braces the rope and has a groove machined therein such that the closure of the two clamps is hexagonal, with 4 areas of pressure on the rope, so as to prevent damaging it. This wall is knurled to assure the grip and to cause self-locking in the event of a malfunction in the actuation.

The casing has special grooving to allow the pins moving the wedges when such wedges are shifted to transversely come close to one another.

The sheaves, with additional guidance device, are arranged such that both ropes are maintained in parallel planes, without the possibility of rubbing against one another when they are under load. The frames of the sheaves and their support shafts are calculated to resist the full rope load (full break hypothesis of the clamps).

For economic, space and simplicity reasons, a single tightening device is used in the embodiment, however this is not an essential feature of the proposed system.

Almost all the elements are subjected to heavy loads, and are exposed to the elements under tough climate conditions. They are therefore designed in steel having suitable features.

1. Automatic system for guiding, retaining and tightening steel wire ropes in cranes, comprising:
at least one self (New) blocking clamp for each end of the rope;
at least one tightening element; and
sheaves for guiding the ropes.

2. Automatic system for guiding, retaining and tightening steel wire ropes in cranes according to claim 1, wherein the clamps comprise a rigid casing inside which there are two independent sliding wedges.

3. Automatic system for guiding, retaining and tightening steel wire ropes in cranes according to claim 2, wherein the wedges comprise an outer wall sliding on the casing and an inner wall bracing the rope.

4. Automatic system for guiding, retaining and tightening steel wire ropes in cranes according to claim 3, wherein the outer wall sliding on the casing is rectified to reduce friction.

5. Automatic system for guiding, retaining and tightening steel wire ropes in cranes according to claim 3, wherein the inner wall bracing the rope has a machining in the form of a groove to prevent damaging the rope and knurling to assure the grip, causing the self-locking.

6. Automatic system for guiding, retaining and tightening steel wire ropes in cranes according to claim 2, wherein the casing has grooving to allow the pins moving the wedges when such wedges are shifted to transversely come close to one another.

7. Automatic system for guiding, retaining and tightening steel wire ropes in cranes according to claim 1, wherein the sheaves comprise an additional guidance device to maintain the ropes parallel without the possibility of rubbing against one another when they are under load.

8. Automatic system for guiding, retaining and tightening steel wire ropes in cranes according to claim 1, wherein the sheaves are located to avoid that the rope rubs or experiences considerable damages and the clamps receive transverse stresses.

9. Automatic system for guiding, retaining and tightening steel wire ropes in cranes according to claim 1, wherein it comprises a hydraulic actuation system for the tightening device and the clamps.

10. Automatic process for guiding, retaining and tightening steel wire ropes in cranes, wherein it comprising:
hoisting the jib;
fixing or releasing the ropes;
tightening ropes;
leveling or aligning the spreader.
